(19) United States
(12) Patent Application Publication
(10) Pub. No.: US 2021/0336198 A1
(43) Pub. Date: Oct. 28, 2021

(54) ORGANIC LIGHT EMITTING DISPLAY PANEL AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Jie LIU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/326,222

(22) PCT Filed: Nov. 1, 2018
(86) PCT No.: PCT/CN2018/113383

§ 371 Date: Feb. 18, 2019

(30) Foreign Application Priority Data
Aug. 31, 2018 (CN) 201811013193.9

(51) Int. Cl. H01L 51/52; H01L 51/56

(52) U.S. Cl. CPC H01L 51/5253; H01L 51/56

(57) ABSTRACT

An organic light emitting display panel includes a backplate, an organic light emitting module disposed on the backplate, and a lip portion of the backplate is defined between an edge of the backplate and an edge of the organic light emitting module. An encapsulation layer is configured to encapsulate the backplate and the organic light emitting module and cover the lip portion. The encapsulation layer includes an encapsulation resin film laminated on the backplate and a metal film disposed on the encapsulation resin film. The metal film extends toward the backplate and bends inwardly within the encapsulation resin film on the lip portion of the backplate to form a groove.

### BACKGROUND OF INVENTION

### 1. Field of Invention

The present invention relates to a display field, and particularly to an organic light emitting display panel and a manufacturing method thereof capable of improving encapsulation effect,

### 2. Related Art

In recent years, with ongoing development of display technology, organic light emitting diode (OLED) devices, as a new display technology, have attracted wide attention due to advantages of being self-luminous, wide viewing angles, high resolution, and low power consumption. In the manufacturing process of OLED displays, surface encapsulation technology has been widely used as the mainstream encapsulation technology for current OLED displays. Particularly, metal encapsulation dominates the market because of its good moisture barrier properties and contribution to achieve compact configuration of products.

Conventionally, due to the limitation of the moisture barrier properties, resin films used in metal encapsulation technology are disposed within a gap between other structural components, wherein the gap is formed with a thickness as small as possible to reduce a size of a passage where moisture can permeate through. A backplate is processed through multiple processing chambers like array, evaporation, and encapsulation processing chambers prior to being transferred to a lamination processing chamber. During the process of transferring the backplate, there might be minor foreign matter getting into inner structures or structure surfaces. FIG. 1 is a schematic view showing a conventional organic light emitting display panel. When a backplate is laminated with a metal film in the lamination processing chamber, remaining foreign matter in a resin film gap h, and affected by pressure, may damage an electroluminescence (EL) layer, and therefore forming a passage where moisture can permeate through, resulting in ineffectiveness of a display device. In addition, an OLED device might be damaged by the pressure, and thus give rise to the occurrence of abnormal dark spots, thereby adversely affecting improvement of product quality. The resin film gap H (as shown in FIG. 2) can be increased to provide larger space for foreign matter and thus to improve tolerance to foreign matter for the OLED device, thereby to prevent structural components from being damaged by the pressure. However, an increase of the resin film gap brings about a larger size of the passage where moisture can permeate through, thereby to lessen moisture barrier function of the resin films.

### SUMMARY OF INVENTION

Accordingly, an object of the present invention is to provide an organic light emitting display panel and a manufacturing method thereof that has a structure to improve encapsulation effect and to significantly reduce thickness of an encapsulation film and a width of a moisture passage under the premise of not reducing the tolerance to foreign matter in encapsulation, thereby to prevent a light emitting layer from not being damaged by foreign matter during encapsulation process and further to effectively barrier outside moisture.

To achieve the above-mentioned object, the organic light emitting display panel of the present invention includes a backplate; an organic light emitting module disposed on the backplate, wherein a lip portion of the backplate is defined between an edge of the backplate and an edge of the organic light emitting module; and an encapsulation layer configured to encapsulate the backplate and the organic light emitting module and covering the lip portion of the backplate, wherein the encapsulation layer comprises an encapsulation resin film laminated on the backplate and a metal film disposed on the encapsulation resin film; wherein the metal film extends toward the backplate and bends inwardly within the encapsulation resin film on the lip portion of the backplate to form a groove.

In one aspect of the present invention, the groove of the metal film comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

In another aspect of the present invention, the end portion of the groove has an aperture width less than or equal to an aperture width of the opening of the groove.

In another aspect of the present invention, the groove is triangular in shape in a perpendicular cross-section of the groove.

In another aspect of the present invention, a third distance is defined between a surface of the organic light emitting module far away from the backplate and the metal film, and the third distance is less than a depth of the groove.

In another aspect of the present invention, the metal film is made of an Invar alloy.

In another aspect of the present invention, the organic light emitting module comprises an anode layer, a light emitting layer, and a cathode layer.

The present invention further provides a method of manufacturing an organic light emitting display panel, comprising: providing a backplate; forming an organic light emitting module on the backplate, wherein a lip portion of the backplate is defined between an edge of the backplate and an edge of the organic light emitting module; providing an encapsulation layer comprising an encapsulation resin film configured to be laminated on the backplate and a metal film disposed on the encapsulation resin film, wherein the metal film is processed in advance through a cold forming process to extend toward the backplate and bend inwardly within the encapsulation resin film on the lip portion of the backplate to form a groove; and laminating the encapsulation layer onto the backplate and the organic light emitting module, wherein the backplate is laminated with the encapsulation layer through the encapsulation resin film, the encapsulation resin film is processed through thermal curing to complete encapsulation of the organic light emitting module, and the groove is disposed within the encapsulation resin film on the lip portion of the backplate.

In one aspect of the present invention, the groove of the metal film comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

In another aspect of the present invention, a third distance is defined between a surface of the organic light emitting module far away from the backplate and the metal film, and the third distance is less than a depth of the groove.

In another aspect of the present invention, before the encapsulation layer is laminated onto the backplate and the organic light emitting display panel, pre-curing the encapsulation resin film, then laminating the pre-cured encapsulation resin film onto the backplate and the organic light emitting module, and then thermo-curing the pre-cured encapsulation resin film.

The present invention further provides an organic light emitting display panel, comprising a backplate; an organic light emitting module comprising an anode layer, a light emitting layer disposed on the anode layer, and a cathode layer disposed on the light emitting layer, wherein the organic light emitting module is disposed on the backplate, and a lip portion of the backplate is defined between an edge of the backplate and an edge of the organic light emitting module; and an encapsulation layer configured to encapsulate the backplate and the organic light emitting module and covering the lip portion of the backplate, wherein the encapsulation layer comprises an encapsulation resin film laminated on the backplate and a metal film disposed on the encapsulation resin film; wherein the metal film extends toward the backplate and bends inwardly within the encapsulation resin film on the lip portion of the backplate to form a groove, and the groove comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

In one aspect of the present invention, the end portion of the groove has an aperture width less than or equal to an aperture width of the opening of the groove.

In another aspect of the present invention, a third distance is defined between a surface of the organic light emitting module far away from the backplate and the metal film, and the third distance is less than a depth of the groove.

In another aspect of the present invention, the metal film is made of an Invar alloy.

The organic light emitting display panel of the present invention utilizes the encapsulation structure that the groove of the metal film extends toward and bends inwardly within the encapsulation resin film on the lip portion of the backplate to effectively reducing a width of the passage where moisture can permeate through, thereby to prevent outside moisture from permeating into the interior of the display panel, and to avoid reducing lifespan of products because of external moisture. Furthermore, a space between the metal film and the organic light emitting module is enough to accommodate foreign matter and can improve tolerance to foreign matter for the encapsulation structure, thereby to prevent the light emitting layer from being damaged by the pressure from the foreign matter during the encapsulation process, and further to improve a yield rate of a product. Accordingly, the organic light emitting display panel of the present invention effectively overcome drawbacks of traditional encapsulation structure that moisture is easily to permeate into interior of a device and foreign matter tends to depress and damage a light emitting layer.

### BRIEF DESCRIPTION OF DRAWINGS

FIG. 1 is a schematic view showing a conventional organic light emitting display panel.

FIG. 2 is another schematic view showing a conventional organic light emitting display panel.

FIG. 3 is a schematic cross-sectional view of an organic light emitting display panel in accordance with an embodiment of the present invention.

FIG. 4 is a schematic cross-sectional view of an organic light emitting display panel in accordance with another embodiment of the present invention.

FIG. 5 is a schematic cross-sectional view of an organic light emitting display panel in accordance with another embodiment of the present invention.

FIG. 6 is a flowchart showing a method of manufacturing an organic light emitting display panel of the present invention.

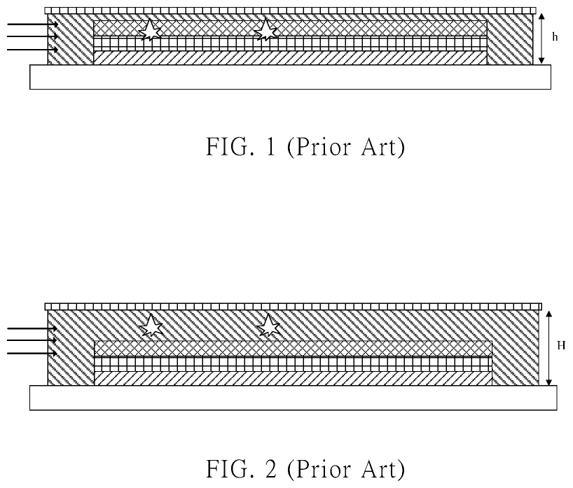

### DESCRIPTION OF PREFERRED EMBODIMENTS

The following embodiments are referring to the accompanying drawings for exemplifying specific implementable embodiments of the present disclosure. Furthermore, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, elements with similar structures are labeled with like reference numerals.

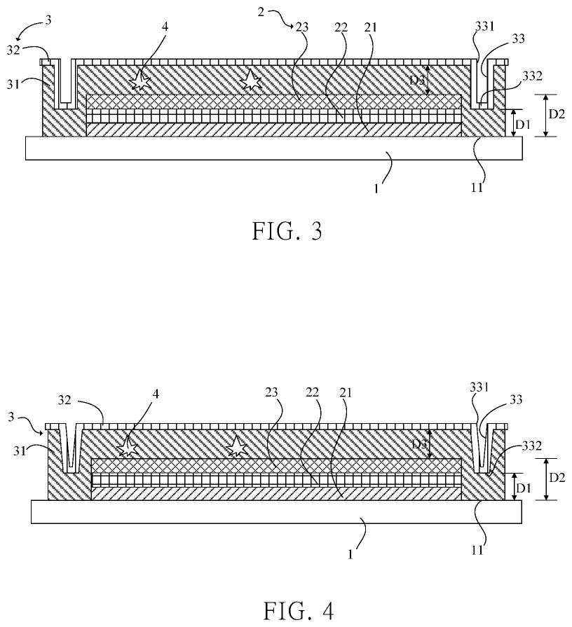

An organic light emitting display panel of the present invention is exemplified as an organic light emitting diode (OLED) display panel. FIG. 3 is a schematic cross-sectional view of an organic light emitting display panel in accordance with an embodiment of the present invention. The organic light emitting display panel includes a backplate 1, an organic light emitting module 2, and an encapsulation layer 3. The organic light emitting module 2 is disposed on the backplate 1 and includes an anode layer 21, a light emitting layer 22 disposed on the anode layer 21, and a cathode layer 23 disposed on the cathode layer 23. Particularly, a lip portion 11 of the backplate 1 is defined between an edge of the backplate 1 and an edge of the organic light emitting module 2.

The encapsulation layer 3 is configured to encapsulate the backplate 1 and the organic light emitting module 2 and to cover the lip portion 11 of the backplate 1. The encapsulation layer 3 includes an encapsulation resin film 31 laminated on the backplate 1 and a metal film 32 disposed on the encapsulation resin film 31, wherein the metal film 32 is completely laminated onto the encapsulation resin film 31 and is made of an Invar alloy. The Invar alloy has the smallest alloy expansion coefficient and is similar to glass in terms of material properties, which avoids stresses due to differences in expansion coefficients. Being distinct from a traditional encapsulation metal film, the metal film 32 of the present invention is configured based on the asymmetry principle to be different from a flat surface structure of a traditional metal film. Specifically, the metal film 32 of the encapsulation layer 3 extends toward the backplate 1 and bends inwardly within the encapsulation resin film 31 on the lip portion 11 of the backplate 1 to form a groove 33. The groove 33 has an opening 331 and an end portion 332 disposed between the opening 331 and the backplate 1.

Please continuously refer to FIG. 3. In the preferable embodiment, a first distance D1 is defined between the end portion 332 and an upper surface of the backplate 1, a second distance D2 is defined between the upper surface of the backplate 1 and a surface of the organic light emitting module 2 far away from the backplate 1, and the first distance D1 is less than the second distance D2. In this manner, under the premise of not changing an interval (i.e. passage) between the metal film 32 and the back plate 1, because the groove 33 of the metal film 32 extends toward and bends inwardly within the encapsulation resin film 31 on the lip portion 11 of the backplate 1, the present invention is capable of effectively reducing a width of the passage where moisture can permeate through, thereby preventing outside moisture from permeating into the interior of the display panel to affect the display and reduce lifespan.

Furthermore, as shown in FIG. 3, a third distance D3 is defined between a surface of the organic light emitting module 2 far away from the backplate 1 and the metal film 32, and the third distance D3 is less than a depth of the groove 33. Because minor foreign matter may get into interior or surfaces of a device structure before the backplate 1 is proceeded to encapsulation process, the third distance D3 can provide space to accommodate the foreign matter, thereby to improve tolerance to the foreign matter for encapsulation structure and to prevent the light emitting layer 22 from being damaged by the pressure from the foreign matter during the encapsulation process, and further improving a yield rate of a product.

FIG. 4 is a schematic cross-sectional view of an organic light emitting display panel in accordance with another embodiment of the present invention. In this embodiment, the end portion 332 of the groove 33 has an aperture width less than or equal to an aperture width of the opening 331 of the groove 33, such that the groove 33 has an inverse trapezoid shape in a perpendicular cross-section of the groove 33, thereby to enhance structural strength of the groove 33. The groove 33 as shown in FIG. 4 can perform a function same as that of the groove 33 as shown in FIG. 3. In other words, each of the grooves 33 of FIG. 3 and FIG. 4 is capable of effectively reducing a width of the passage where moisture can permeate through, thereby preventing outside moisture from permeating into the interior of the display panel.

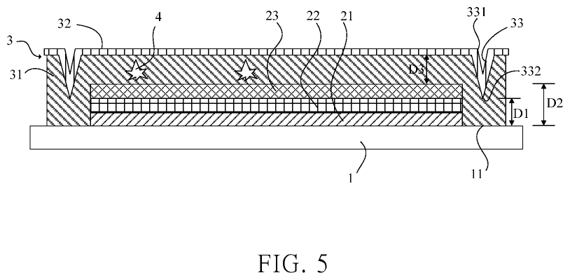

FIG. 5 is a schematic cross-sectional view of an organic light emitting display panel in accordance with another embodiment of the present invention. In this embodiment, the groove 33 has a tringle shape in a perpendicular cross-section of the groove 33 and can improve structural strength of the groove 33. Each of the grooves 33 of FIG. 3 and FIG. 4 is capable of effectively reducing a width of the passage where moisture can permeate through, thereby preventing outside moisture from permeating into the interior of the display panel. The groove 33 as shown in FIG. 5 can perform a function same as that of the groove 33 as shown in FIG. 3. In other words, each of the grooves 33 of FIG. 5 and FIG. 4 is capable of effectively reducing a width of the passage where moisture can permeate through, thereby preventing outside moisture from permeating into the interior of the display panel.

The organic light emitting display panel of the present invention utilizes the encapsulation structure that the groove 33 of the metal film 32 extends toward and bends inwardly within the encapsulation resin film 31 on the lip portion 11 of the backplate 1 to effectively reducing a width of the passage where moisture can permeate through, thereby to prevent outside moisture from permeating into the interior of the display panel, and to avoid reducing lifespan of products because of external moisture. Furthermore, a space between the metal film 32 and the organic light emitting module 2 is enough to accommodate foreign matter and can improve tolerance to foreign matter for the encapsulation structure, thereby to prevent the light emitting layer 22 from being damaged by the pressure from the foreign matter during the encapsulation process, and further to improve a yield rate of a product. Accordingly, the organic light emitting display panel of the present invention effectively overcome drawbacks of traditional encapsulation structure that moisture is easily to permeate into interior of a device and foreign matter tends to depress and damage a light emitting layer.

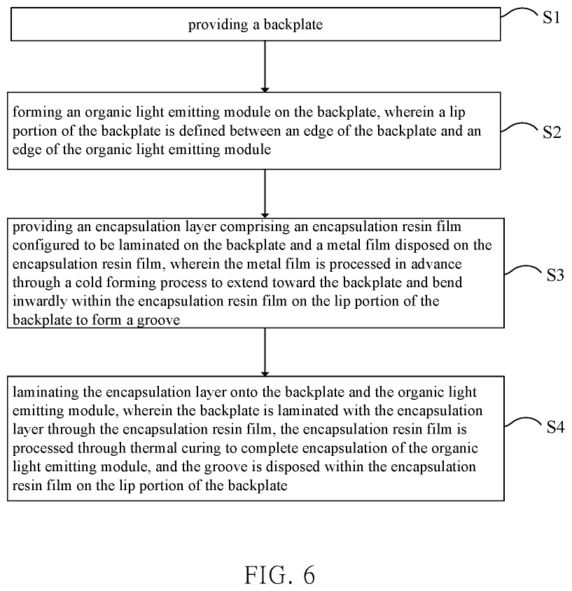

FIG. 6 is a flowchart showing a method of manufacturing an organic light emitting display panel of the present invention. The method includes steps as described below.

Step S1: providing a backplate;

Step S2: forming an organic light emitting module on the backplate, wherein a lip portion of the backplate is defined between an edge of the backplate and an edge of the organic light emitting module;

Step S3: providing an encapsulation layer comprising an encapsulation resin film configured to be laminated on the backplate and a metal film disposed on the encapsulation resin film, wherein the metal film is processed in advance through a cold forming process to extend toward the backplate and bend inwardly within the encapsulation resin film on the lip portion of the backplate to form a groove; and

Step S4: laminating the encapsulation layer onto the backplate and the organic light emitting module, wherein the backplate is laminated with the encapsulation layer through the encapsulation resin film, the encapsulation resin film is processed through thermal curing to complete encapsulation of the organic light emitting module, and the groove is disposed within the encapsulation resin film on the lip portion of the backplate.

Particularly, the encapsulation resin film is made of organic polymer (such as polyethylene terephthalate, PET) and is added with a water absorbing material (such as calcium oxide or the like) and a hydrophobic material. Before the encapsulation layer is laminated onto the backplate and the organic light emitting display panel, pre-curing the encapsulation resin film, then laminating the pre-cured encapsulation resin film onto the backplate and the organic light emitting module, and then thermo-curing the pre-cured encapsulation resin film.

Other structures of the organic light emitting display panel manufactured according to the method of manufacturing the organic light emitting display panel are described in the previous paragraphs, and will not be repeated herein.

It is understood that the invention may be embodied in other forms within the scope of the claims Thus the present examples and embodiments are to be considered in all respects as illustrative, and not restrictive, of the invention defined by the claims

What is claimed is:

1. An organic light emitting display panel, comprising:
a backplate;
an organic light emitting module disposed on the backplate, wherein a lip portion of the backplate is defined between an edge of the backplate and an edge of the organic light emitting module; and
an encapsulation layer configured to encapsulate the backplate and the organic light emitting module and covering the lip portion of the backplate, wherein the encapsulation layer comprises an encapsulation resin film laminated on the backplate and a metal film disposed on the encapsulation resin film;
wherein the metal film extends toward the backplate and bends inwardly within the encapsulation resin film on the lip portion of the backplate to form a groove.

2. The organic light emitting display panel of claim 1, wherein the groove of the metal film comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

3. The organic light emitting display panel of claim 2, wherein the end portion of the groove has an aperture width less than or equal to an aperture width of the opening of the groove.

4. The organic light emitting display panel of claim 1, wherein the groove is triangular in shape in a perpendicular cross-section of the groove.

5. The organic light emitting display panel of claim 1, wherein a third distance is defined between a surface of the organic light emitting module far away from the backplate and the metal film, and the third distance is less than a depth of the groove.

6. The organic light emitting display panel of claim 1, wherein the metal film is made of an Invar alloy.

7. The organic light emitting display panel of claim 1, wherein the organic light emitting module comprises an anode layer, a light emitting layer, and a cathode layer.

8. A method of manufacturing an organic light emitting display panel, comprising:
providing a backplate;
forming an organic light emitting module on the backplate, wherein a lip portion of the backplate is defined between an edge of the backplate and an edge of the organic light emitting module;
providing an encapsulation layer comprising an encapsulation resin film configured to be laminated on the backplate and a metal film disposed on the encapsulation resin film, wherein the metal film is processed in advance through a cold forming process to extend toward the backplate and bend inwardly within the encapsulation resin film on the lip portion of the backplate to form a groove; and
laminating the encapsulation layer onto the backplate and the organic light emitting module, wherein the backplate is laminated with the encapsulation layer through the encapsulation resin film, the encapsulation resin film is processed through thermal curing to complete encapsulation of the organic light emitting module, and the groove is disposed within the encapsulation resin film on the lip portion of the backplate.

9. The method of manufacturing the organic light emitting display panel of claim 8, wherein the groove of the metal film comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

10. The method of manufacturing the organic light emitting display panel of claim 8, wherein a third distance is defined between a surface of the organic light emitting module far away from the backplate and the metal film, and the third distance is less than a depth of the groove.

11. The method of manufacturing the organic light emitting display panel of claim 8, wherein before the encapsulation layer is laminated onto the backplate and the organic light emitting display panel, pre-curing the encapsulation resin film, then laminating the pre-cured encapsulation resin film onto the backplate and the organic light emitting module, and then thermo-curing the pre-cured encapsulation resin film.

12. An organic light emitting display panel, comprising:
a backplate;
an organic light emitting module comprising an anode layer, a light emitting layer disposed on the anode layer, and a cathode layer disposed on the light emitting layer, wherein the organic light emitting module is disposed on the backplate, and a lip portion of the backplate is defined between an edge of the backplate and an edge of the organic light emitting module; and
an encapsulation layer configured to encapsulate the backplate and the organic light emitting module and covering the lip portion of the backplate, wherein the encapsulation layer comprises an encapsulation resin film laminated on the backplate and a metal film disposed on the encapsulation resin film;
wherein the metal film extends toward the backplate and bends inwardly within the encapsulation resin film on the lip portion of the backplate to form a groove, and the groove comprises an opening and an end portion disposed between the opening and the backplate, a first distance is defined between the end portion and an upper surface of the backplate, a second distance is defined between the upper surface of the backplate and a surface of the organic light emitting module far away from the backplate, and the first distance is less than the second distance.

13. The organic light emitting display panel of claim 12, wherein the end portion of the groove has an aperture width less than or equal to an aperture width of the opening of the groove.

14. The organic light emitting display panel of claim 12, wherein a third distance is defined between a surface of the organic light emitting module far away from the backplate and the metal film, and the third distance is less than a depth of the groove.

15. The organic light emitting display panel of claim 12, wherein the metal film is made of an Invar alloy.
